(19) United States
(12) Patent Application Publication
(10) Pub. No.: US 2026/0324307 A1
(43) Pub. Date: Oct. 15, 2026

(54) SCALABLE PRODUCTION OF GRAPHENE STRUCTURES

(71) Applicant: LayerLogic AB, Göteborg (SE)

(72) Inventors: Munis KHAN, Västra Frölunda (SE); Avgust YURGENS, Sävedalen (SE)

(21) Appl. No.: 19/486,184

(22) PCT Filed: Jun. 25, 2024
(86) PCT No.: PCT/SE2024/050623

§ 371 Date: Nov. 20, 2025

(30) Foreign Application Priority Data
Jun. 27, 2023 (SE) 2350790-8

(51) Int. Cl. H10P 14/20; C01B 32/182; H10D 30/47

(52) U.S. Cl. CPC H10P 14/3406; C01B 32/182; H10D 30/481; H10P 14/2923

(57) ABSTRACT

Graphene structures, graphene-based devices and methods of fabrication thereof. The graphene structure detachably arranged and formed on a substrate includes a graphene layer formed on the substrate. Further, the graphene structure includes a first patterned structure extending above a first side of the graphene layer formed on the substrate. The graphene structure further includes an attached cover layer over the first patterned structure and the graphene layer.

### TECHNICAL FIELD

The present disclosure relates to stacked graphene structures as well as methods of forming such a graphene structure. Particularly, embodiments and aspects of the present disclosure relate to graphene-based devices comprising the stacked graphene structure and applications thereof.

### BACKGROUND

Graphene, since its discovery, has emerged as a highly promising two-dimensional (2D) material in the field of electronics and optoelectronics. Its flexibility, transparency, and excellent conductivity have paved the way for advancements in several scientific fields such as flexible electronics, sensing, and transistor devices to name a few. The exceptional mechanical properties of graphene have garnered substantial attention for use in stretchable electronic devices. Additionally, graphene possesses desirable properties such as high chemical stability, a wide optical absorption spectrum, excellent transparency, and electrical sensitivity to biochemicals, making it a promising material for displays, light harvesting devices, and biosensors.

Chemical vapor deposition (CVD) of graphene on copper foils has been found to provide a scalable approach for obtaining high-quality single-layer graphene, which can then be used for further processing and intended applications. High-quality graphene refers to material free from contamination, wrinkles, cracks, or any other defects, characterized by its single-crystalline nature.

However, transferring graphene to a different substrate is often required for the subsequent applications. The widely used approach involves the deposition of a sacrificial polymer layer on the grown graphene layer, followed by the removal of the copper substrate and dissolution of the polymer layer. Unfortunately, this process is tedious and usually leads to contamination of the graphene surface by polymer residues. The contaminations lead to worsening of graphene's electrical properties, in particular, to lower carrier mobility of the transferred graphene compared to exfoliated graphene. Despite ongoing efforts, the mass production of high-quality graphene devices using scalable and cost-effective methods remains a challenge and there is a need in the field of graphene production as well graphene-based devices for development of versatile solutions, which address some of the above-mentioned drawbacks.

### SUMMARY

It is accordingly an objective of the present invention to improve the current state of the art and to mitigate at least some of the above-mentioned problems.

These and other objectives are achieved by providing a method of forming a stacked graphene structure, the formed stacked graphene structure and graphene-based devices fabricated by the proposed method as defined in the appended independent and dependent claims. The term exemplary is in the present context to be understood as serving as an instance, example or illustration.

According to a first aspect of the present disclosure, there is provided a method of fabricating a stacked graphene structure. The method comprising forming a graphene layer on a substrate and forming a first patterned structure extending above a first side of the graphene layer formed on the substrate. The method further comprises forming, above the first patterned structure, a cover layer by attaching the cover layer over the first patterned structure and the graphene layer formed on the substrate; wherein the stacked graphene structure at least comprises the graphene layer, the first patterned structure and the attached cover layer.

In various exemplary embodiments, the method may further comprise forming the first patterned structure by depositing the first patterned structure on top of the first side of the graphene layer formed on the substrate. Additionally or alternatively, the method may comprise forming the first patterned structure by depositing the first patterned structure at one or more edge portions of the graphene layer.

According to several embodiments, the method may further comprise attaching the cover layer on top of a first side of the first patterned structure as well as on top of the first side of the graphene layer formed on the substrate. In more detail, the method may comprise attaching the cover layer in physical contact with the first side of the first patterned structure, by gluing the cover layer on top of the first side of the first patterned structure and the first side of the graphene layer. The method may further comprise providing a permanent attachment of the cover layer on top of the first side of the first patterned structure and the first side of the graphene layer.

According to several embodiments, the method may further comprise forming a second layer stack between the graphene layer formed on the substrate and the first patterned structure by depositing the second layer stack on top of the first side of the graphene layer formed on the substrate. The method may further comprise forming the first patterned structure on top of a first side of the deposited second layer stack; wherein the stacked graphene structure may further comprise the second layer stack.

In several embodiments, the method may further comprise attaching the cover layer on top of the first patterned structure and the first side of the deposited second layer stack. In more detail, the method may comprise attaching the cover layer in physical contact with the first side of the first patterned structure and the first side of the deposited second layer stack, by gluing the cover layer on top of the first patterned structure and the first side of the deposited second layer stack. Thereby, the method may further comprise providing a permanent attachment of the cover layer on top of the first patterned structure and the first side of the deposited second layer stack.

In several embodiments, the first patterned structure may comprise a conductive material including metal or a conductive ink and the first patterned structure may be adapted as a conductive electrode. In some embodiments, the first patterned structure may entirely be made of the conductive material.

In several embodiments, the second layer stack may be made of a dielectric material.

In several embodiments, the cover layer may comprise an insulating material. The insulating material may comprise any one of plastic, glass or sapphire.

In several embodiments, the method may further comprise separating the stacked graphene structure from the substrate by means of detaching the stacked graphene structure such that a second side of the graphene layer opposite to the first side of the graphene layer may be exposed.

In several embodiments, the method may further comprise detaching the stacked graphene structure from the substrate by means of any one of an electrochemical delamination, a mechanical delamination, or an etching process.

In several embodiments, the method may further comprise forming a third layer stack by depositing the third layer stack on top of the exposed second side of the graphene layer which is separated from the substrate. Additionally or alternatively, the method may comprise forming a second patterned structure extending above the second side of the graphene layer. Accordingly, the present inventors have realized that graphene layer is capable of withstanding several fabrication steps resulting in several hundred nanometers of the fabricated stack on top of it, which may include the first patterned structure, and the second layer stack (e.g., a dielectric layer). It is very intriguing that graphene maintains its electrical and physical characteristics when the graphene layer and the patterned structures fabricated on the graphene layer are released from the substrate according to embodiments herein with the support of the cover layer.

According to a second aspect of the present disclosure, there is provided a graphene structure detachably arranged and formed on a substrate, wherein the graphene structure comprises a graphene layer formed on the substrate. The graphene structure further comprises a first patterned structure extending above a first side of the graphene layer formed on the substrate; and an attached cover layer over the first patterned structure and the graphene layer.

In several embodiments, the graphene structure may further comprise a second layer stack arranged between the graphene layer and the first patterned structure, the second layer stack being deposited on top of the first side of the graphene layer; wherein the first patterned structure may be arranged on top of a first side of the deposited second layer stack.

According to a third aspect of the present disclosure, there is provided a graphene-based sensor device or a graphene field-effect-transistor device comprising a stacked graphene structure fabricated by a method according to any one of the embodiments of the method according to the first aspect of the present disclosure.

According to a fourth aspect of the present disclosure, there is provided a graphene field-effect-transistor device formed by and comprising a stacked graphene-based structure according to any one of the embodiments of the method according to the first aspect or any one of the embodiments of the graphene structure according to the second aspect of the present disclosure. The transistor device comprises a graphene layer having a first side and a second side opposite the first side. The transistor device further comprises a gate dielectric layer stack arranged at the first side of the graphene layer. The transistor device further comprises a first patterned gate electrode arranged at a first side of the gate dielectric layer stack. The transistor device further comprises a cover layer attached over the first patterned gate electrode and the first side of the gate dielectric layer stack. The attached cover layer is configured to encompass the first patterned gate electrode and further to support the first patterned gate electrode, the gate dielectric layer stack, and the graphene layer. The transistor device further comprises a second pattered electrode structure comprising a first source electrode portion and a second drain electrode portion arranged at opposite ends of the graphene layer; wherein the second side of the graphene layer is exposed.

In several embodiments, the transistor device may further comprise a cover dielectric layer arranged at the second side of the graphene layer, and configured to cover the exposed second side of the graphene layer.

According to a fifth aspect of the present disclosure, there is provided a method of fabricating a stacked graphene structure, the method comprising forming a first patterned structure extending above a first side of a cover layer configured to support the first patterned structure. The method comprises forming a pre-patterned cover layer, wherein the first patterned structure is made of a conductive material. The method further comprises attaching the pre-patterned cover layer over a graphene layer formed on a copper foil substrate, wherein the stacked graphene structure at least comprises the graphene layer, and the attached pre-patterned cover layer.

In several embodiments, the method of the fifth aspect may further comprise attaching the pre-patterned cover layer, by gluing the pre-patterned cover layer on top of a first side of the graphene layer. This way, a first side of the patterned electrode structure, and a first surface of the cover layer are arranged in physical contact with the first side of the graphene layer. Thereby, the method may further comprise providing a permanent attachment of the pre-patterned cover layer on top of the first side of the graphene layer.

According to a sixth aspect of the present disclosure, there is provided a stacked graphene structure detachably arranged and formed on a copper foil substrate. The graphene structure comprises a graphene layer formed on the copper foil substrate. The graphene structure comprises a pre-patterned cover layer permanently attached on top of a first side of the graphene layer, wherein the pre-patterned cover layer comprises a first patterned structure made of a conductive material and extending above a first side of the pre-patterned cover layer configured to support the first patterned structure.

Further features and advantages of the invention will become apparent when studying the appended claims and the following description. The skilled person in the art realizes that different features of the present disclosure may be combined to create embodiments other than those explicitly described hereinabove and below, without departing from the scope of the present disclosure.

Further embodiments of the different aspects are defined in the dependent claims.

It is to be noted that all the embodiments, elements, features and advantages associated with the first aspect also analogously apply to the second, third, fourth, fifth, and the sixth aspects of the present disclosure.

These and other features and advantages of the present disclosure will in the following be further clarified in the following detailed description.

### BRIEF DESCRIPTION OF DRAWINGS

Further objects, features, and advantages of embodiments of the disclosure will appear from the following detailed description, reference being made to the accompanying drawings. The drawings are not to scale.

FIGS. 1a-g show a schematic cross-sectional side view illustration of a stacked graphene structure according to several embodiments of the present disclosure.

FIGS. 2a-e show a schematic cross-sectional side view illustration of another stacked graphene structure according to several embodiments of the present disclosure.

FIGS. 3a-g show a schematic cross-sectional side view illustration of yet another stacked graphene structure according to several embodiments of the present disclosure.

FIGS. 4a-d show a schematic cross-sectional side view illustration of still another stacked graphene structure according to several embodiments of the present disclosure.

FIG. 5 shows a flowchart of a method according to several embodiments of the present disclosure.

FIG. 6 shows a flowchart of a method according to several embodiments of the present disclosure.

### DETAILED DESCRIPTION

In the present detailed description, embodiments of the present disclosure will be discussed with the accompanying figures. In the following description of exemplary embodiments, the same reference numerals denote the same or similar components. It should be noted that the person skilled in the art will understand that the invention may be practiced without these details and in any other types or variants of the elements or features than the embodiments shown in the appended drawings.

The following description may use terms such as “top”, “bottom”, “over”, “inner”, “outer”, “side”, “edge”, “ridge”, “distal”, “proximal”, “front”, “back” etc. Different components, layers and structures herein may be described as having one or more sides, each of which may be considered as having a respective surface. These terms generally refer to the views and orientations as shown in the drawings. The terms are used for the reader's convenience only and shall not be construed as limiting.

In the context of the present invention the directions and orientations such as vertical, horizontal, longitudinal, and lateral directions and extensions need to be interpreted broadly and generally refer to the geometrical extensions of objects in a coordinate system such as a three-dimensional Cartesian coordinate system. The spatial extensions and positions of objects may be defined in at least one plane of the coordinate system e.g., by using x, y, z coordinates and their corresponding angles.

It is also to be understood that the terminology used herein is for purpose of describing particular embodiments only and is not intended to be limiting. It should be noted that, as used in the specification and the appended claim, the articles “a”, “an”, “the”, and “said” are intended to mean that there are one or more of the elements unless the context clearly dictates otherwise. Thus, for example, reference to “a unit” or “the unit” may refer to more than one unit in some contexts, and the like. Furthermore, the words “comprising”, “including”, “containing” do not exclude other elements or steps. It should be emphasized that the term “comprises/comprising” when used in this specification is taken to specify the presence of stated features, integers, steps, or components. It does not preclude the presence or addition of one or more other features, integers, steps, components, or groups thereof. The term “and/or” is to be interpreted as meaning “both” as well and each as an alternative. The term “obtaining” is herein to be interpreted broadly and encompasses receiving, retrieving, collecting, acquiring, and so forth.

The term “forming” in the present context and for the proposed solutions, methods, implementations, and processes encompasses any suitable fabrication and material deposition technique in the art of producing the graphene structures and devices according to aspects and embodiments herein.

It will also be understood that, although the terms first, second, etc. may be used herein to describe various elements or features, these elements should not be limited by these terms. These terms are only used to distinguish one element from another.

Various aspects of the disclosure will hereinafter be described in conjunction with the appended drawings to illustrate and not to limit the disclosure, wherein like designations denote like elements, and variations of the described aspects are not restricted to the specifically shown embodiments but are applicable on other variations of the disclosure.

As mentioned earlier, significant progress has been made in the synthesis of graphene, notably through methods like chemical vapor deposition (CVD), capable of producing graphene films with robust structural integrity on transition-metal substrates, commonly copper. Many graphene-related technologies however, necessitate use of specific substrates such as semiconductors and metal oxides. Consequently, additional processes are often required to transfer CVD graphene to the desired technological substrate. Achieving this transfer process while preserving the pristine attributes of the graphene demands meticulous care and precise process control. It is imperative to safeguard against any introduction of defects during transfer, emphasizing the need for rigorous attention to detail and adherence to best practices. The proposed methods and devices herein provide simpler and more sustainable fabrication approaches for achieving high-quality graphene devices.

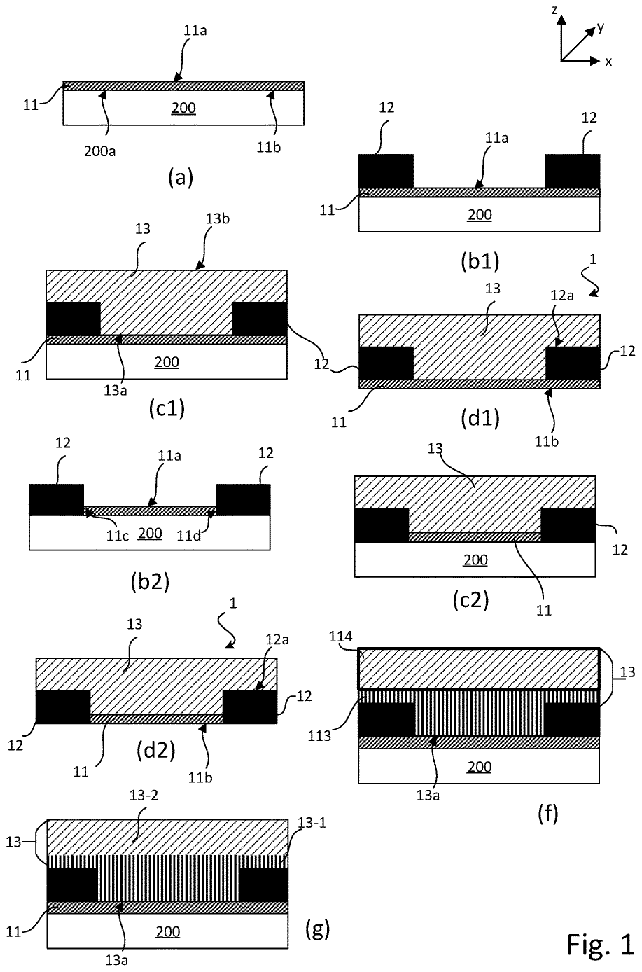

FIGS. 1a-d show a schematic cross-sectional side view of a stacked graphene structure 1 according to several embodiments and aspects herein. The term stacked herein is to elucidate that the graphene structure may have several material layers being arranged over and/or on top of one another in various embodiments. The stacked graphene structure 1 may be interchangeably referred to as the graphene structure 1, or assembly 1 in the rest of this description for simplicity only. The figures illustrate several layers and arrangement thereof in the graphene structures and devices presented herein, however depicted dimensions, extensions and thicknesses of layers are not to scale and shall not be construed as limiting.

As mentioned previously, the proposed graphene structure 1 herein may be fabricated with any methods and fabrication processes such as, but not limited to, material deposition by evaporation, CVD, or sputtering, material wet-or dry etching, and patterning techniques using photo- or e-beam lithography, nanoimprint lithography, or ink-jet printing, known in the art. The graphene structure 1 is detachably or otherwise referred to as removably arranged and formed on a substrate 200. As shown in FIG. 1(a), the graphene layer 11 is arranged on a top surface 200a of the substrate 200, wherein a second side 11b (bottom side 11b) of the graphene layer 11 is in physical contact with the top surface 200a of the substrate 200. A first side 11a (top side 11a) of the graphene layer 11 in FIG. 1a is exposed. The extensions and orientations of the substrate 200, graphene layer 11 and the other components of the graphene structures, e.g., top or bottom sides in FIGS. 1-4 are explained relative to the Cartesian coordinate system shown in FIG. 1. These terms are used for the reader's convenience only and shall not be construed as limiting. For instance, the longest extensions of the substrate 200 and the arranged graphene layer 11 thereon are shown to be in the x-direction. The graphene layer 11 is deposited on the surface 200a extending parallel with the longest direction of the substrate 200. In some other examples, the longest extension of the substrate 200 may be in the y-direction. The term detachably or removably in the present context is to be construed that the graphene structure is fabricated, patterned and otherwise functionally prepared on the substrate 200. However, the graphene layer as well as the stacked structure fabricated on the graphene layer are adapted to be detached from the substrate on demand. In other words, functional components for forming a graphene structure or a graphene-based device comprising the graphene structure are fabricated entirely or partly on the substrate 200. The fabricated graphene structures 1 may then be removed or detached by the proposed methods herein in order to be utilized for intended exemplary applications. In use, the graphene structure 1 or the exemplary graphene devices comprising any one of various graphene structures 1 proposed herein are in a detached state from the substrate 200. However, the graphene structures 1 presented herein may be fabricated and stored for later use while still being arranged on the substrate 200. A step of detachment according to several aspects and embodiments herein may ensue utilization of the graphene structures 1 for the intended applications or for further processing and subsequent after-detachment fabrication steps. In several embodiments, the substrate 200 may be a metallic substrate. More specifically, the metallic substrate 200 may be a metal foil, the metal foil may be a copper foil 200. In some embodiments, the metallic substrate 200 may be a metallic slab or block. When referring to the “substrate 200” in the present disclosure, it is to be construed that any one of the above-mentioned suitable alternatives may be utilized. An advantage is provided by using copper foils according to various embodiment herein as the substrate 200 in that depositing thin metal films on solid substrates such as Si/SiO₂ using cumbersome physical vapor deposition (thermal or electron beam evaporation, sputtering etc.) is alleviated. Additionally, using copper foil substrates makes the fabrication process even more cost effective and time efficient.

In FIG. 1a, a layer of graphene 11 is formed e.g., by CVD deposition on the substrate 200. In FIG. 1b1 and 1b2, a first patterned structure 12 is formed extending above a first side 11a of the graphene layer formed on the substrate 200. In the alternative in FIG. 1b1, the first patterned structure 12 may be formed above the graphene layer 11 such that it is in physical and electrical contact with the top surface or first side 11a of the graphene layer 11. Stated differently, the first patterned structure 12 is deposited on top of the first side 11a of the graphene layer 11. The patterned structure 12 may be deposited on top of the first surface 11a. In several embodiments, the first patterned structure 12 may be made of a conductive material including metal or a conductive ink. The first patterned structure may be adapted to function as a conductive electrode. The contacts 12 deposited on the top surfaces 11a of the graphene layer 11 in physical and electrical contact with the graphene layer 11, may also be referred to as top contact arrangement herein. In several embodiments, however, the first patterned structure 12 may be deposited at one or more edge portions 11c, 11d of the graphene layer 11. Stated otherwise, the first patterned structure 12 may include edge contacts in electrical and physical connections with the edge portions 11c, 11d of the graphene layer 11 as shown in the exemplary FIG. 1b2 and FIG. 1d2.

The stacking direction of the first patterned structure 12 in either of the above alternatives is substantially perpendicular to the graphene layer 11. The first patterned structure 12 and the graphene layer 11 have a respective height profile (representative of respective thicknesses of the first patterned structure 12 and the graphene layer 11) extending in the z-direction in the examples of FIGS. 1-4. The z-direction corresponds to the stacking direction of the first patterned structure 12 as well as a second layer stack 14 and a cover layer 13 while they are arranged on the substrate 200. In the present context, when a first patterned structure is mentioned to be extending above the first side of the graphene layer, it is to be construed that the height of the first patterned structure 12 extends beyond the height of the formed graphene layer 11. In other words, a first side 12a (top side 12a) of the first patterned structure 12 has a greater elevation than the first side 11a (top side 11a) of the graphene layer with respect to the top surface 200a of the substrate 200. Furthermore, the first patterned structure extending above the first side of the graphene layer would be in physical and electrical contact with the graphene layer and/or the substrate as explained above for the alternatives of FIG. 1b1 or 1b2.

The first patterned structure 12 may be formed by means of etching or lift-off fabrication processes. For instance, a sacrificial photoresist layer (not shown) with the intended pattern of the patterned structure may be coated on the first side 11a of the graphene layer 11, and a first layer stack (not specifically shown) intended for forming the first patterned structure may be deposited on the sacrificial layer. After a lift-off process, the residues of the first layer stack not being part of the intended pattern are removed leaving behind the first patterned structure 12. Alternatively, the first layer stack (not specifically shown) may be deposited on the first side 11a of the graphene layer 11 and then etched away by means of chemical wet etching, leaving behind the first patterned structure 12. The above exemplary methods among other fabrication methods may be utilized for forming various patterned structures according to the present disclosure.

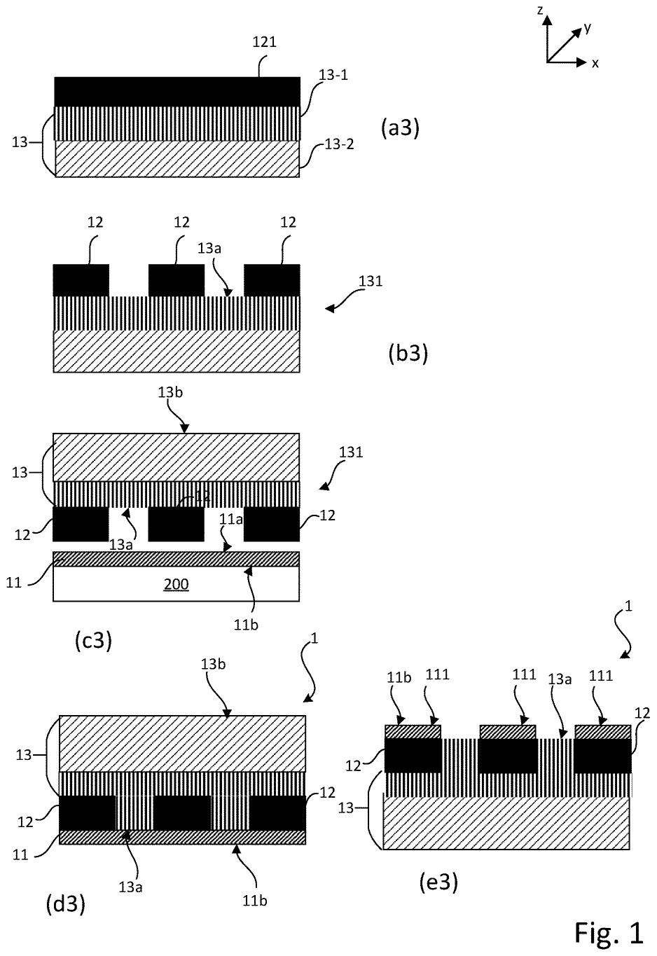

In various embodiments, the graphene structure 1 further comprises a cover layer 13 or alternatively referred to herein as cladding layer 13 or support layer 13. The cover layer 13 is formed above the first patterned structure 12 and the graphene layer 11 by attaching the cover layer 13 over the first patterned structure 12 and the graphene layer 11. By “attaching over” in the present context it is meant that the cover layer 13 is either on top of and directly in physical contact with the first patterned layer 12 and the graphene layer 11 or it is attached to an intermediate layer, e.g., layer 14, with reference to FIGS. 2a-e, arranged on the graphene layer 11. In any case, the cover layer 13 at least partially surrounds and covers the one or more layers beneath the cover layer 13. In several embodiments, the cover layer 13 may entirely cover the top surface of the layer(s) on which it is deposited e.g., the entire surface of the first side 11a of the graphene layer 11 and the first patterned layer 12 in FIGS. 1a-d.

In several embodiments herein, the cover layer may be made of an insulating material comprising any one of plastic, thermoplastic, glass, sapphire, or other dielectric materials. The plastic may comprise different suitable types of plastic such as PET/EVA (polyethylene terephthalate/Ethylene-vinyl acetate). In several aspects and embodiments, the cover layer 13 may be attached to the graphene layer and the first patterned layer by means of gluing the cover layer 13. The gluing may be performed by means of using an adhesive material. Accordingly, the process of gluing in the present context is to be construed as permanently attaching the cover layer to the layers underneath the cover layer by means of glue layer 113 or the adhesive material. In several embodiments and for the devices shown in FIGS. 1-4 , the glue layer 113 is configured to conform to the topography of the underneath layer. In several embodiments, a separate layer of adhesive 113 may be applied to the underneath layers and the insulating portion 114 of the cover layer 13 be placed on top of the adhesive layer 113. In several embodiments however, the cover layer 13 may comprise an integrated glue layer 13-1 i.e. an adhesive layer acting as glue. For instance as shown in FIG. 1g, in several embodiments the cover layer 13 may comprise a dual layer structure, e.g., a PET/EVA combination. The EVA sub-layer 13-1 will act as the adhesive layer permanently attaching the top insulating PET sub-layer 13-2 onto the underneath graphene layer 11 and the first patterned layer 12. In some embodiment, the glue layer can be an epoxy or cyanoacrylate (super glue), while the top sub-layer maybe any other polymer, glass or Si wafer. The glue layer 113, 13-1 will accordingly conform to the boundaries and topography of the underneath surfaces as e.g. shown in FIG. 1g for the PET/EVA combination. In some embodiments, the insulating part 114 of the cover layer 13 may be made of a rigid material e.g. glass 114. The rigid insulating portion 114 will adhere to the underneath glue layer 113 that conforms to the topography of the underneath surfaces as shown in FIG. 1f. In the present context and the in the rest of this description when referring to the cover layer 13 it comprises both the glue layer 113, 13-1 and the insulating layer 114, 13-2 attached to the underneath surfaces by the glue layer 113, 13-1 unless specified otherwise. The example arrangements of insulating layers 114, 13-2 and glue layers 113, 13-1 are therefore intended to have been applied and present in several embodiments illustrated in FIGS. 1-4, even if not specifically shown, e.g. in FIG. 1c1.

The gluing may comprise laminating the cover layer 13. In some embodiments, the gluing may comprise partially melting, by heating, the cover layer 13 in order for the cover layer 13 to adhere to the underneath surface. In several exemplary embodiments, the lamination is enabled by means of using a polymeric adhesive, assisted by a standard hot-rolling lamination process. This step involves laminating the prepared graphene stack 1 to the cover layer 13 by means of a laminator.

In several embodiments, the cover layer may be attached on top of the first side 12a of the first patterned structure 12 and the first side 11a of the graphene layer formed on the substrate 200 as shown in FIG. 1c1, 1d1, 1c2 and 1d2. Gluing the cover layer 13 provides a permanent attachment of the cover layer 13 to the surface(s) on which it is glued. A first surface 13a (may alternatively be referred to as first side 13a or bottom side 13a) of the permanently glued cover layer 13 is arranged in physical contact with the surface(s) onto which it is glued. It should be clear to the skilled person that the bottom side 13a of the cover layer 13 may be a bottom surface 13a of the glue layer 113, 13-1 of the cover layer 13 in physical contact with the underneath surfaces, as shown in FIGS. 1f, 1g.

Furthermore, it should be clear to the skilled person, when it is mentioned throughout the description that a first component, e.g., the cover layer 13 is attached on top of a second component, e.g., the first side 12a of the first patterned structure 12, the term “top” is used for the reader's convenience only and shall not be construed as limiting. It is equally conceivable that the first side 12a of the first patterned structure 12 can be attached on top of the first side 13a of the cover layer 13, if the vertical orientation of the example device 1 in FIG. 1c1, 1d1, 1c2 and 1d2 is inverted.

By permanent attachment in the present context, it is meant that the attachment is irreversible and enduring. An advantage is provided this way that the cover layer 13 is utilized as the final supporting substrate 13 and forms a base of the devices, on which the entire device 1, 110, 120, 130 will rest, e.g., after separation from the copper substrate 200, as well as during use and operation of the devices 1, 110, 120, 130. In more detail, a second surface 13b (may alternatively be referred to as second side 13b or top side 13b) of the cover layer 13 would serve as the base having a bottom surface 13b of the final devices 1, 110, 120, 130.

In some exemplary embodiments, the graphene structure 1 or assembly 1 may be fabricated by forming the graphene layer or film 11 on the substrate 200. Further, electrical contacts 12 (first patterned structure) may be fabricated in electrical connection to the graphene film 11 as shown in FIGS. 1a-d. An assembly may be formed by gluing the supporting substrate 13 or cover layer 13 to the graphene film 11 formed on the substrate 200. Removing i.e., detaching the substrate 200, e.g., the metal foil 200 from the assembly thereby reveals the graphene film 11 at the bottom 11b of the assembly 1. Thus, a multilayer assembly 1 can be provided which at least comprises the graphene film 11, the electrical contacts 12 to the graphene film 11, and the supporting substrate 13 glued to the graphene film 11. In several embodiments, the cover layer 13 may be a flexible support substrate configured to support the graphene structures 1. An advantage is thus achieved for fabrication of flexible graphene-based devices with various applications in the field of flexible electronics. Several graphene-based devices such as sensor devices e.g., biosensors, transistor devices e.g., field effect transistors (FET), medical devices such as electrostimulation devices for wound healing, etc., can be manufactured by the methods and the graphene structures 1 proposed herein. Accordingly, said devices advantageously may comprise various graphene structures 1 as explained herein suitable for their intended applications.

As mentioned previously, the two-dimensional structure of graphene has several benefits over bulk semiconductors, such as silicon, used in standard FETs. A FET is an electrical component which uses a nearby electric field and its associated voltage differential to modulate the current flow. FETs are generally devices with three terminals, or electrodes: a semiconductor channel runs between two of these electrodes-the source and the drain while a third, called the gate, acts as the control. The voltage differential applied to the gate allows or blocks the charge transport through the semiconductor channel depending on its direction and strength. Graphene field-effect transistors (GFETs) assume the typical FET device structure and insert a graphene channel between the source and drain. Being graphene, a lattice of carbon atoms that is only one atom thick, the channels in GFETs have high sensitivity to external stimuli, which can be exploited on a wide variety of applications such as photo sensing, magnetic sensing, and bio-sensing. Since most semiconductor transistor sensors are three-dimensional, electric charge changes at the surface of channel do not always penetrate deeper into the device. This can limit the sensitivity of the conventional devices. On the other hand, as the graphene in a GFET is only one carbon atom thick, the entire channel is now the surface, which exposes the whole channel to any molecules present in the nearby environment. This is for instance shown in a graphene device 110 in FIG. 2e comprising the graphene structure 1 which will be explained further in the following. The graphene-based device 110 in this example may be a GFET device 110 or a graphene-based sensor device 110 having the second side 11b of the graphene layer 11 exposed, which may be brought to immediate vicinity of e.g., a cell culture or a tissue with a multitude of molecules present therein.

Current diagnostic tools face a multitude of challenges in meeting the clinical requirements for high speed, throughput, accuracy, cost, and simplicity of use. The prepared GFETs according to the embodiments herein are expected to be utilized for a variety of applications in the biomedical field among others. For instance, infection diagnostic kits may be developed by the proposed graphene-based devices that will be functionalized by receptors capturing infection biomarkers. Such devices may be used as plug-and-play disposable chips with a micro-SD jack to simplify the contacting the chips. Miniaturized, low cost, rapid, highly sensitive, and specific graphene-based sensors comprising the graphene structures 1 can be developed for detecting bacterial infections in the hospital settings. These devices will be suitable for detection and subspecies-level categorization of infectious bacteria, particularly highly virulent strains. The aforementioned devices may also be ready for incorporation into biomedical devices (e.g., catheters, implants), allowing their timely replacement in case of bacterial attachment.

By utilizing the presented graphene structures 1 in biosensors, more economic and reliable devices for detecting harmful bacteria and viruses can be produced. This also includes the detection of bacteria or fungi in food and the detection of food decay, thereby helping to use food more efficiently and at the same time avoid food poisoning. In addition to bio-sensing, the prepared GFETs hold tremendous promise in the fields of low-cost electronics for future high-speed wireless communication and non-invasive inspection at terahertz frequencies. Graphene, with its unique combination of flexibility and high carrier velocity, can provide new opportunities for terahertz electronics. Power sensors based on graphene structures 1 herein can be utilized as fast and sensitive detectors over a wide part of the electromagnetic spectrum. Graphene, due to its very high mobility and low charge carrier density as well as its mechanical flexibility, appears to be ideally suited as the sensing material in Hall effect sensors. Graphene-based Hall sensors fabricated based on the graphene structures herein are expected to outperform silicon and other III/V semiconductor-based rigid sensors. This is additionally advantageous as graphene-based Hall sensors significantly outperform all other technologies on flexible substrates. Magnetic field sensors are widely used in several key industries such as consumer electronics, automotive, healthcare and robotics, where they provide position and speed detection, switching applications or current monitoring. By providing efficient, flexible, and scalable graphene structures 1 and method of fabrication thereof according to the present disclosure enormous amounts of time and resources can be used in a significantly more efficient manner. Even further, electrostimulation systems and devices for applications such as tissue stimulation, wound healing and the like can be devised based on the graphene structures herein. For instance, the device 110 in FIG. 2e or the devices 1 having the graphene structure 1 in FIG. 1d1 and 1d2 can utilize the exposed part 11b of graphene as well as the electrodes 12 to interface with a bio-environment such as a tissue portion. Devices can thus be utilized for reading electrical or electrochemical signals form the tissue and its surrounding environment, operating as biosensors, as well as transmitting stimulating electrical signals to the tissue. Excellent transparency of the graphene layer in the graphene structures 1 would also allow combining these devices with laser light-based technologies.

In the present context wherein, it is mentioned that a first layer or structure is above another layer or structure i.e., a second layer or structure, it is to be construed that the first layer is either on top of the second layer with physical and/or electrical contact or alternatively, there may be one or more intermediate layers present in between the first and second layers.

For instance, as shown in FIGS. 2a-2e, the first pattered structure 12 may be arranged above the graphene layer 11 without having any physical or electrical connection with the graphene layer 11. In this example, a second layer stack 14 i.e., an intermediate layer 14 is arranged between the graphene layer 11 formed on the substrate 200 and the first patterned structure 12 by depositing the second layer stack 14 on top of the first side 11a of the graphene layer 11 formed on the substrate. Therefore, the first patterned structure 12 may be deposited on top of a first side 14a of the deposited second layer stack 14 i.e., being in physical contact with the second layer stack 14 but not with the graphene layer 11. The cover layer 13 may thus be attached on top of the first patterned structure 12 i.e., in physical contact with the first side 12a of the first patterned structure 12 and the first side 14a of the deposited second layer stack 14. In several embodiments and aspects, the second layer stack may be made of a dielectric material. In several embodiments, the dielectric material may be any suitable dielectric material. More specifically in some examples, the dielectric material 14 may be a Parylene N dielectric layer. The present inventors have realized that using Parylene N has several advantages, namely Parylene N serves as a clean substrate for graphene, and can be deposited in room temperature by straightforward CVD deposition. Moreover, it is flexible, cost-effective and can be fabricated in a scalable deposition process. It also possesses a high breakdown voltage and has a dielectric constant similar to SiO₂. Unlike other dielectrics (ALD Al₂O₃, HfO₂) no seed layer is needed for Parylene N.

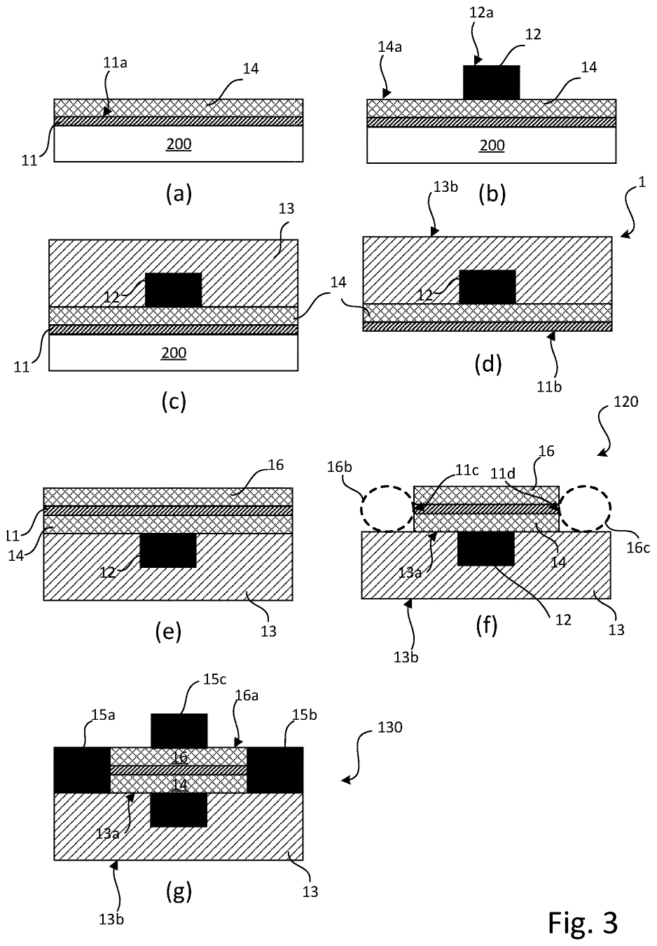

In another exemplary embodiment as shown in FIGS. 4a-d, the first patterned structure 15a, 15b may be fabricated in form of the edge contacts as explained with respect to FIG. 1b2, 1c2 and 1d2. The difference in the example of FIG. 4 is that the second layer stack 14 is also arranged on top of the first side 11a of the graphene layer 11 covering the first side 11a. The edge contact structure or electrodes 15a, 15b are in physical and electrical contact with the two lateral sides 11c, 11d, i.e., edge portions of the graphene layer 11.

In some exemplary embodiments as shown in the example FIG. 4b, one or more openings 14b, 14c may be formed in the insulating dielectric layer 14, which reveals edges of the graphene film. In more detail, removing parts of the dielectric layer and/or graphene layer corresponding to the one or more openings 14b, 14c, exposes edge portions 11c, 11d of the graphene film. Note that the illustrated openings 14b, 14c in FIG. 4b simply serve the purpose of conveying that edge contacts are deposited in the space formed as a result of the material removal, without depicting any precise dimensions of the formed space nor a specific order of the removal/deposition steps. It is clear to the skilled person that the edge contacts are deposited after the openings are prepared. Further, electrical edge contacts 15a, 15b may be formed in electrical and physical connection to the revealed edge portions 11c, 11d of the graphene film by depositing a metal through the openings 14b, 14c in the insulating dielectric layer 14. The assembly 1 may be formed by gluing the cover or supporting layer 13 to the dielectric layer 14 on top of the graphene film 11 and the electrically conducting first patterned structure 15a, 15b as previously mentioned and illustrated in FIG. 4c. Removing i.e. detaching the substrate 200, e.g., the metal foil 200 from the assembly 1 thereby reveals the graphene film 11 at the second side 11b at the bottom of the assembly 1 shown in FIG. 4d.

In some exemplary embodiments, the graphene structure 1 or assembly 1 may be fabricated by forming the graphene film 11 on the substrate 200. Further, a dielectric insulating layer 14 may be deposited on top of the graphene film 11 formed on the metal foil 200. An electrically conducting gate structure i.e., the first patterned structure 12 being a gate electrode 12 may be formed on top of the dielectric insulating layer 14. The dielectric insulating layer 14 may be referred to as the gate dielectric layer 14. The assembly 1 may be formed by gluing the supporting substrate 13 to the dielectric layer 14 and the gate electrode 12 on top of the graphene film 11. The substrate 200 comprising the metal foil may be removed i.e., detached from the assembly 1 thereby revealing the graphene film 11 at the bottom of the assembly 1 i.e., the exposed side of graphene layer 11b as shown in the examples of FIGS. 2a-d. Furthermore, in one or more post-processing steps, electrical edge contacts 15a, 15b may be formed in electrical and physical connection to the revealed sides, i.e., edge portions 11c or 11d of the graphene film 11. The cover layer 13 is depicted to be used as the supporting layer 13 on which the entire device 110 will rest.

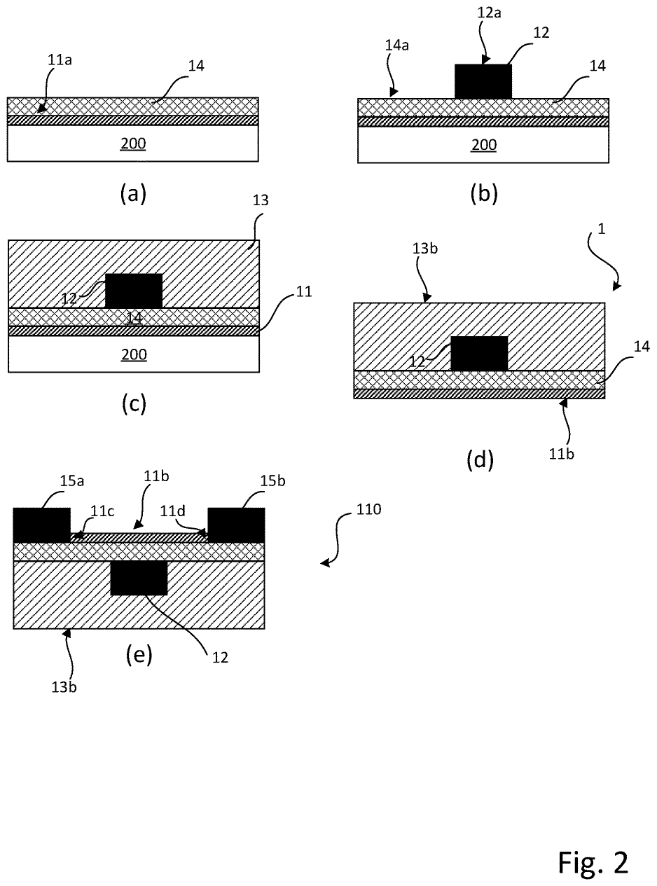

Accordingly, a graphene-field effect transistor device 110 formed by and comprising the stacked graphene structure 1 is illustrated in FIG. 2e. The GFET 110 may be referred to as a back-gate GFET herein. The GFET 110 comprises the graphene layer 11 having the first side 11a and the second side 11b opposite the first side. Further, the GFET device 110 comprises the gate dielectric layer stack 14 arranged at the first side 11a of the graphene layer. The first patterned gate electrode 12 may be arranged at the first side 14a of the gate dielectric layer stack 14. The support layer 13 is attached e.g., by lamination or gluing over the first patterned gate electrode 12 and the first side of the gate dielectric layer stack 14a. The attached cover layer 13 may be configured to encompass the first patterned gate electrode 12 and further to support the first patterned gate electrode, the gate dielectric layer stack, and the graphene layer. A second pattered electrode structure 15a, 15b comprising a first source electrode portion e.g., electrode 15a and a second drain electrode portion e.g., electrode 15b may be arranged at opposite ends e.g. edge portions 11c, 11d of the graphene layer 11 having the second side 11b of it exposed. It should be clear to the skilled person in the art that devices 1, 110, 120, 130 according to several embodiments herein may be fabricated with top or edge contacts based on the required design constraints and/or applications. The back-gate GFET device 110 may further comprise a cover dielectric layer 16 arranged at the second side 11b of the graphene layer and configured to cover the exposed second side 11b of the graphene layer 11, as e.g., shown in the device 120 in FIG. 3f and device 130 in FIG. 3g. In some example embodiments, the dielectric material 16 may be a Parylene N dielectric layer 16. With the proposed processes herein, scalable, sustainable, and simpler fabrication of high-quality graphene devices can be achieved. The patterning of gate electrodes on top of graphene on copper substrate enables fabrication of back-gate GFETs, which traditionally is done on Si/SiO₂ substrates using conventional transfer methods. The most traditional method involves transferring graphene (from copper) first using wet transfer method and then patterning devices. The microfabrication techniques used in the embodiments herein are significantly simpler, sustainable, and economical compared to the traditional process flows used both in academics and industry. All the steps are extremely scalable and suitable for mass production. The proposed methods can also be used for stacking multiple layers of graphene for various tangible applications.

As mentioned previously, the graphene structure 1 may be detachably arranged on the substrate 200. Therefore, in several aspects and embodiments herein, the stacked graphene structure 1 can be separated from the substrate 200 by means of detaching the stacked graphene structure 1 such that a second side 11b of the graphene layer 11 opposite to the first side 11a of the graphene layer is exposed to the external environment such as air. In several embodiments, the stacked graphene structure may be detached from the substrate 200 by means of electrochemical delamination. Additionally or alternatively, the stacked graphene structure 1 may be detached from the substrate 200 by means of a mechanical delamination, or an etching process e.g., a wet chemical etching process by e.g., diluted nitric acid (HNO₃), iron trichloride (FeCl₃), or ammonium persulfate (NH₄)₂S₂O₈).

The present inventors have realized that the graphene layer 11 being a single layer of carbon atoms having a thickness around 0.34 nm is capable to withstand several fabrication steps resulting in several hundred nanometers of the fabricated stack on top of it, which may include the first patterned structure 12, the second layer stack 14 (e.g., the dielectric layer), etc.

It is very intriguing that the graphene preserves its electrical and physical characteristics when the graphene layer and the patterned structures are released from the substrate 200 according to embodiments herein with the support of the cover layer 13.

Attachment of the cover layer over the graphene layer and the entire patterned structures still being arranged on the substrate 200, is also a unique feature of the proposed solutions herein. Separation i.e., detaching the prepared graphene assembly 1 from copper substrate 200 by electrochemical delamination, or mechanical delamination provides an additional advantage of reusing the copper substrate 200, since it is not dissolved in the process of detachment. This way a more cost-efficient and scalable fabrication process can be achieved. Detaching the prepared graphene assembly 1 from copper substrate 200 by electrochemical delamination provides a further advantage of maintaining electronic properties of the graphene layer to a great extent unaffected. Accordingly, the proposed methods, structures and devices herein may achieve a significantly higher carrier mobility, in some cases at least fourfold higher, or at least sevenfold, or at least eightfold compared to prior art.

The detached graphene structures 1 according to various exemplary embodiments herein are illustrated in FIG. 1d1, FIG. 1d2, FIGS. 2d-e, FIGS. 3d-g, and FIG. 4d. It should be noted that the present inventors have realized that the cover layer 13 can be utilized as a base and support layer 13 on which the entire graphene structure 1 may rest in its detached state.

According to several embodiments and aspects, one or more appropriate post processing steps may also be carried out on the detached graphene structures 1 in order to finalize devices comprising the graphene structure 1 for their intended applications. For example, a second patterned structure 15 may be formed such that it may extend above the second side 11b of the graphene layer 11, which is exposed after detachment. This e.g., is shown for the structure 110 in FIG. 2e, wherein a pair of electrically conductive edge contact electrodes 15a and 15b are formed in physical and electrical contact with the sides, i.e., edge portions 11c, 11d of the graphene layer 11, while the second side of the graphene layer 11b is exposed. It is to be noted that the first patterned structure 12, e.g., the top/edge contact electrodes 12, and/or the second layer stack 14, or the second patterned structures 15, e.g., the edge contact electrodes 15a, 15b shown in the respective FIGS. 1-4 may have any suitable thicknesses such as at least 10 nm, 20 nm, 50 nm, 100 nm, 200 nm, or 300 nm, and/or at most 300 nm, or 1000 nm, depending on the intended design and applications.

In a similar example, depicted in FIG. 3e, f and g, the graphene structure 1 may undergo a post processing step of arranging a third layer stack 16 by depositing the third layer stack 16 on top of the exposed second side 11b of the graphene layer 11 which is separated from the substrate 200. This is shown for structure 120 and 130 in FIGS. 3f and 3g. In this example, a pair of electrically conductive edge contacts 15a and 15b are formed in physical and electrical contact with the sides 11c, 11d of the graphene layer 11, while the second side 11b of the graphene layer is covered by the third layer stack 16. In FIG. 3g, an additional second patterned structure 15c may be arranged on top of a first side 16a of the third layer stack 16 in the structure 130. In some example embodiments, the third layer stack 16 may be made of Parylene N dielectric material.

Accordingly, in some exemplary embodiments after removing the metal foil e.g., copper foil from the assembly 1 and revealing the second side 11b of the graphene film at the bottom of the assembly, an encapsulation insulating layer 16 e.g., the dielectric layer 16 may be arranged at the surface of the revealed graphene film. Furthermore, openings 16b, 16c may be formed in the encapsulation insulating layer 16, which reveals the edge portions 11c, 11d of the graphene film 11 as shown in FIG. 3f. The openings may be formed by means of any of the patterning methods as previously explained. Removing portions of the graphene film corresponding to the openings, through the openings in the encapsulation insulating dielectric layer 16 may form lateral edges 11c, 11d of the graphene film. Edge electrical contacts 15a, 15b may be formed in electrical and physical connections to the revealed lateral edges 11c, 11d of the graphene film 11 by depositing a metal through the openings in the encapsulation insulating layer 16 as shown for the exemplary graphene-based device 120 in FIG. 3f.

In some exemplary embodiments, an additional electrically conducting structure 15c may be deposited on the outer surface i.e., side 16a of the encapsulation insulating layer 16 as shown for the exemplary graphene-based device 130 in FIG. 3g. The additional electrically conducting structure 15c may be an electrically conducting gate structure 15c in a graphene-based transistor device 130.

As mentioned earlier with regard to the conventional fabrication techniques of graphene devices, after conventional wet transfer of graphene layer to the target substrate, electrodes are applied onto the graphene layer through micro-nano fabrication processes like photolithography, evaporation, and lift-off. These metal electrodes serve to transmit and receive electrical signals to and from the graphene. In one approach, contact electrodes are deposited on wet-transferred graphene on the Si/SiO₂ substrate. These contact electrodes are known as top contacts. In another approach referred to as bottom contacts, CVD graphene on copper foils is transferred via wet transfer onto target substrates (e.g. a Si/SiO₂ substrate) with pre-deposited metal electrodes. Bottom contacts offer an advantage of minimizing additional processing on the already-transferred graphene, resulting in reduced surface contamination and improved electrical properties. However, the conventional bottom-contact devices still suffer from above-discussed drawbacks of wet-transferred and contaminated graphene onto pre-deposited metal electrodes. Moreover, for utilizing graphene devices for chemical sensing in liquid mediums, the metal electrodes undergo a isolation process using insulating materials such as metal oxides or polymers to avoid parasitic currents. This involves an additional photolithographic patterning step to coat or grow insulating materials over the fabricated graphene devices. Common isolation methods include spin coating SU8 photoresists or depositing metal oxides (e.g., Al₂O₃) using atomic layer deposition. However, these methods not only add an extra step to the fabrication of graphene devices but also risk contaminating the graphene surface.

The present inventors have devised methods and techniques to overcome the above-mentioned drawbacks of the conventional approaches in depositing contact electrodes. In accordance with several embodiments and aspects herein as shown in FIG. 1a3-1e3, a stacked graphene structure 1 detachably arranged and formed on a copper foil substrate 200 is provided. The stacked graphene structure comprises a graphene layer 11 formed on the copper foil substrate 200. The stacked graphene structure 1 further comprises a pre-patterned cover layer 131 permanently attached on top of a first side 11a of the graphene layer 11. The pre-patterned cover layer 131 comprises a first patterned structure 12 made of a conductive material and extending above a first side 13a of the cover layer 13 configured to support the first patterned structure 12. In other words, cover layer 13 pre-patterned with the electrodes 12 being deposited on top of the first surface 13a of the cover layer 13 forms the pre-patterned cover layer 131. The conductive electrodes 12 may be deposited by means of metal evaporation, ink-jet printing, screen printing, etc. on the first surface 13a of the cover layer 13 configured to support the patterned electrodes 12. Conventional photolithography methods or any other micro/nano fabrication methods may be used for patterning a deposited layer 121 of conductive material in order to form the patterned electrodes 12 on the cover layer 13 and forming a pre-patterned cover layer 131. The pre-patterned cover layer 131 may then be attached on top of the first side 11a of the graphene layer 11 formed on the substrate 200. In several embodiments, the first side 12a of the patterned electrode structure 12, and the first surface 13a of the cover layer 13 may be arranged in physical contact with the first side 11a of the graphene layer formed on the substrate 200. Similar to the approach depicted in as shown in FIG. 1c1, 1d1, 1c2 and 1d2, no wet transfer of CVD graphene is required, thus unnecessary contamination of the graphene layer 11 is advantageously prevented. The pre-patterned cover layer 131 may be attached to the graphene layer 11 by means of gluing. Gluing the pre-patterned cover layer 131 provides a permanent attachment of the cover layer 13 to the surface(s) on which it is glued. The first surface 13a of the permanently-glued pre-patterned cover layer 131 is arranged in physical contact with the surface(s) onto which it is glued. An advantage is provided this way that the pre-patterned cover layer 131 is utilized as the final supporting substrate 13, i.e., form the base of the devices, on which the entire device 1 will rest. In more detail, a top surface 13b of the pre-patterned cover layer 131 would serve as a bottom surface 13b of the final devices 1. Similar to the cover layer 13, the pre-patterned cover layer 131 may be made of an insulating material comprising any one of plastic, thermoplastic, glass, sapphire, or other dielectric materials. In several embodiments, the pre-patterned cover layer 131 may comprise plastic formed of a dual-layer structure, the dual layer structure comprising a first sub-layer made of ethylene-vinyl acetate, EVA, and a second sub-layer made of polyethylene terephthalate, PET. In this example, the cover layer comprises a flexible cover layer 13 e.g. a dual layer PET/EVA combination having an integrated EVA glue layer 13-1 and a PET insulating layer 13-2 as show in FIG. 1a3. When the pre-patterned cover layer is brought in contact with the graphene layer (FIG. 1c3), the glue layer 13-1 conforms to the topography of the underneath graphene layer 11 and the patterned electrodes 12 as shown in FIG. 1d3.

Similar to embodiments of FIG. 1d1 and 1d2, the graphene structure 1 comprising the pre-patterned cover layer 131 may be separated from the copper substrate 200 by means of electrochemical delamination. Additionally or alternatively, the graphene structure 1 may be detached (FIG. 1d3) from the substrate 200 by means of a mechanical delamination, or an etching process e.g., a wet chemical etching process. Patterning the graphene layer 11 into required geometry may subsequently be performed by photolithography and oxygen plasma etching as shown in FIG. 1e3.

An additional advantage of the above-described method is isolation of metal electrodes 12 with the graphene layer 11 itself for electrochemical sensing in liquid medium. The attached graphene layer in physical contact with the pre-deposited metal electrodes 12 of the cover layer 13 is arranged to act as an isolation layer. It is to be noted that isolation is not equivalent to electrical insulation in the present context.

This saves not only an extra step of required isolation by insulating materials, but also prevents further contamination of the graphene layer 11 by avoiding extra processing steps. In several embodiments, the stacked graphene structure 1 may be separated from the copper foil substrate 200 by several detachment processes such as electrochemical delamination, a mechanical delamination, or an etching process as previously explained. In several embodiments, the stacked graphene structure 1 may comprise a patterned graphene layer 111, wherein the patterned graphene layer 111 may be arranged to cover a first side 12a of the first patterned structure 12. Accordingly, a second side 11b of the patterned graphene layer 111 may be exposed.

Another advantage achieved by the proposed methods herein is alleviating degradation of electrical properties of graphene severely impacted by conventional wet transfer methods. For instance, measured charge carrier mobility of wet-transferred graphene on a Si/SiO₂ substrate is 1000 cm²/Vs, while using the above described method, a charge carrier mobility of 10 000cm²/Vs is attained in the graphene devices presented herein.

The proposed method can be used to fabricate liquid-gated graphene field-effect transistors with on chip integrated metal electrodes. The integrated metal electrodes allow replacement of bulky external reference electrodes. Fabricated GFETs may be used to develop infection diagnostic kits based on graphene, functionalized by receptors capturing infection biomarkers. The devices fabricated using the disclosed fabrication methods herein significantly out-perform the commercially available devices on Si/SiO₂ using wet-transferred graphene in terms of electrical properties, flexibility and scalability of fabrication processes as well as cost efficiency.

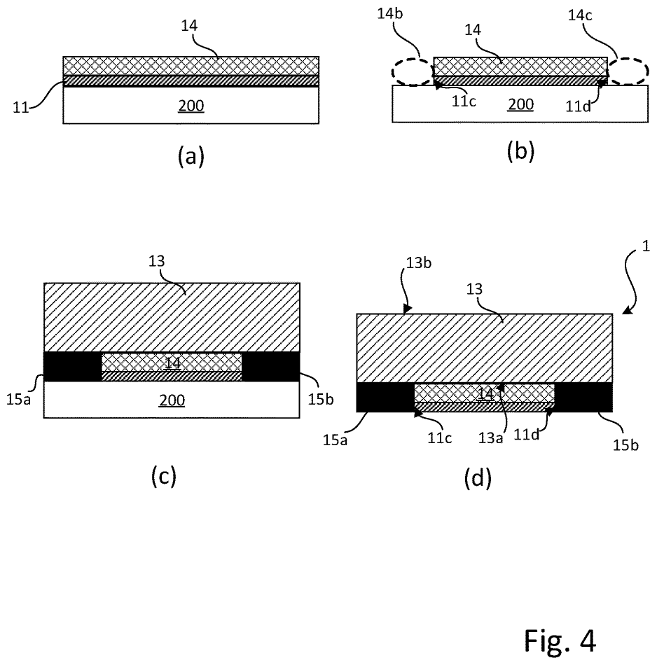

FIG. 5 shows a flowchart of a method 500 according to several embodiments and aspects of the present disclosure. The method 500 is presented for fabricating a stacked graphene structure 1. The method 500 comprises forming 501 a graphene layer 11 on a substrate 200. In several embodiments, the substrate may be a metallic substrate such as a metal foil. The metal foil may be a copper foil. The method further comprises forming 503 a first patterned structure extending above a first side of the graphene layer formed on the substrate. Further, the method comprises forming 505, above the first patterned structure, a cover layer by attaching 505a the cover layer over the first patterned structure and the graphene layer formed on the substrate, wherein the stacked graphene structure at least comprises the graphene layer 11, the first patterned structure 12 and the attached cover layer 13.

In some embodiments, the method may further comprise forming the first patterned structure by depositing the first patterned structure on top of the first side of the graphene layer formed on the substrate.

In several embodiments, the method may further comprise attaching 505a the cover layer on top of a first side 12a of the first patterned structure 12 and the first side of the graphene layer formed on the substrate. In more detail, the method may comprise attaching 505a the cover layer 13 in physical contact with the first side 12a of the first patterned structure 12, by gluing the cover layer 13 on top of the first side 12a of the first patterned structure and the first side 11a of the graphene layer. The method may further comprise providing 506 a permanent attachment of the cover layer 13 on top of the first side 12a of the first patterned structure and the first side of the graphene layer.

In several embodiments, the method may further comprise forming 507 a second layer stack 14 between the graphene layer 11 formed on the substrate and the first patterned structure 12 by depositing the second layer stack on top of the first side of the graphene layer formed on the substrate. The method may further comprise forming the first patterned structure on top of a first side 14a of the deposited second layer stack 14, wherein the stacked graphene structure may further comprise the second layer stack. In several embodiments, the second layer stack may be made of a dielectric material.

In several embodiments, the method may further comprise attaching 505a the cover layer on top of the first patterned structure and the first side of the deposited second layer stack. In more detail, the method 500 may comprise attaching 505a the cover layer 13 in physical contact with the first side 12a of the first patterned structure 12 and the first side 14a of the deposited second layer stack 14, by gluing 505a the cover layer 13 on top of the first patterned structure 12 and the first side 14a of the deposited second layer stack. Thereby, the method may further comprise providing 506 a permanent attachment of the cover layer 13 on top of the first patterned structure 12 and the first side 14a of the deposited second layer stack.

In several exemplary embodiments, the first patterned structure may be made of a conductive material including metal or a conductive ink and the first patterned structure may be adapted as a conductive electrode.

In several embodiments, the cover layer may be made of an insulating material comprising any one of plastic, glass or sapphire.

In several embodiments, the method may further comprise separating 509 the stacked graphene structure from the substrate by means of detaching 509 the stacked graphene structure such that a second side of the graphene layer opposite to the first side of the graphene layer may be exposed. By the second side of the graphene layer being exposed, it is to be construed that the second side is revealed and is in direct communication with its surrounding environment i.e., its immediate vicinity.

In several embodiments, the method may further comprise detaching the stacked graphene structure from the substrate by means of any one of an electrochemical delamination, a mechanical delamination, or an etching process.

In several embodiments, the method may further comprise forming 511 a third layer stack 16 by depositing the third layer stack on top of the exposed second side of the graphene layer which is separated from the substrate. Additionally or alternatively, the method may further comprise forming 513 a second patterned structure extending above the second side of the graphene layer.

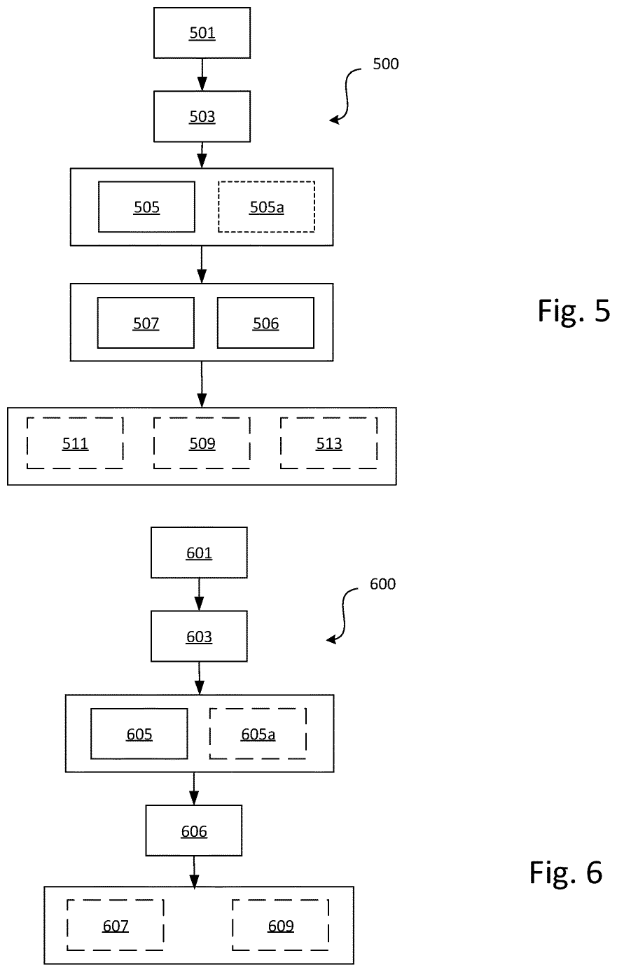

FIG. 6 shows a flowchart of a method 600 according to several embodiments and aspects of the present disclosure. The method 600 is presented for fabricating a stacked graphene structure 1. The method 600 comprises forming 601 a first patterned structure 12 extending above a first side 13a of a cover layer 13 configured to support the first patterned structure 12. Thereby, a pre-patterned cover layer 131 is accordingly formed 603. The first patterned structure 12 may be made of a conductive material including metal or a conductive ink. The first patterned structure may be adapted to function as a conductive electrode 12. The first patterned electrode structure 12 may be realized by depositing a layer of the conductive material on top of the first side 13a of the cover layer 13 and patterning the deposited layer by means of lithography methods as explained previously. The method 600 further comprises attaching 605 the pre-patterned cover layer 131 over a graphene layer 11 formed on a copper foil substrate 200, wherein the stacked graphene structure 1 at least comprises the graphene layer 11 and the attached pre-patterned cover layer 131.

In several embodiments, the method 600 may further comprise attaching 605a the pre-patterned cover layer 131, by gluing 605a the pre-patterned cover layer 131 on top of a first side 11a of the graphene layer. This way, a first side 12a of the patterned electrode structure 12, and a first surface 13a of the cover layer 13 are arranged in physical contact with the first side 11a of the graphene layer 11. Thereby, the method may further comprise providing 606 a permanent attachment of the pre-patterned cover layer 131 on top of the first side 11a of the graphene layer 11.

In several embodiments, the method 600 may further comprise separating 607 the stacked graphene structure 1 from the copper foil substrate 200 by means of detaching 607 the stacked graphene structure such that a second side 11b of the graphene layer 11 opposite to the first side 11b of the graphene layer 11 may be exposed. By the second side of the graphene layer being exposed, it is to be construed that the second side is revealed and is in direct communication with its surrounding environment i.e., its immediate vicinity. In several embodiments, the method 600 may further comprise detaching the stacked graphene structure from the substrate by means of any one of an electrochemical delamination, a mechanical delamination, or an etching process.

In some embodiments, the method 600 may comprise patterning 609 the graphene layer 11 in the detached stacked graphene structure 1 in order to form a patterned graphene layer 111. The patterned graphene layer 111 may be arranged to cover a first side 12a of the first patterned structure 12, and wherein the second side 11b of the patterned graphene layer (111) may be exposed.

The surrounding environment mentioned above, in several embodiments may be liquid mediums. The proposed graphene devices herein may thus be used for chemical sensing in liquid mediums. The exposed part 11b of graphene layer as well as the electrodes 12 may interface with a bio-environment such as a tissue portion. Devices can thus be utilized for reading electrical or electrochemical signals form the tissue and its surrounding environment, operating as biosensors, as well as transmitting stimulating electrical signals to the tissue.

In several embodiments, the patterned graphene layer 111 may have portions (not specifically shown), which are not arranged on the patterned electrodes 12 but on other portions of the bottom side 13a of the cover layer 13. In various embodiments, the graphene layer may be utilized as the isolation layer for the electrodes 12.

It will be appreciated that the above description is merely exemplary in nature and is not intended to limit the present disclosure, its application or uses. While specific examples have been described in the specification and illustrated in the drawings, it will be understood by those of ordinary skill in the art that various changes may be made, and equivalents may be substituted for elements thereof without departing from the scope of the present disclosure as defined in the claims. Where method steps are explained, it should be appreciated that the order with which the steps are performed is not intended to be limited to the specific examples and thus, one or more steps of the methods herein may be performed in a different order or simultaneously with other method steps. Furthermore, modifications may be made to adapt a particular situation or material to the teachings of the present disclosure without departing from the essential scope thereof. Various graphene structures and devices presented herein may advantageously be fabricated using any of the embodiments of the proposed fabrication methods 500 or 600.

Therefore, it is intended that the present disclosure not to be limited to the particular examples illustrated by the drawings and described in the specification as the best mode presently contemplated for carrying out the teachings of the present disclosure, but that the scope of the present disclosure will include any embodiments falling within the foregoing description and the appended claims. Reference signs mentioned in the claims should not be seen as limiting the extent of the matter protected by the claims, and their sole function is to make claims easier to understand.

1. A method of fabricating a stacked graphene structure, the method comprising:
forming a graphene layer on a copper foil substrate;
forming a first patterned structure extending above a first side of the graphene layer formed on the copper foil substrate; and
forming, above the first patterned structure, a cover layer by attaching the cover layer over the first patterned structure and the graphene layer,
wherein the stacked graphene structure comprises at least the graphene layer, the first patterned structure and the attached cover layer.

2. The method according to claim 1, wherein the method further comprises:
forming the first patterned structure by depositing the first patterned structure on the top of the first side of the graphene layer, and/or
the method further comprises:
attaching the cover layer in physical contact with a first side of the first patterned structure, by gluing the cover layer on the top of the first side of the first patterned structure and the first side of the graphene layer; and
thereby providing a permanent attachment of the cover layer on the top of the first side of the first patterned structure and the first side of the graphene layer.

3. (canceled)

4. The method according to claim 1, wherein the method further comprises:
forming a second layer stack, made of Parylene N dielectric material, between the graphene layer formed on the copper foil substrate and the first patterned structure by depositing the second layer stack on top of the first side of the graphene layer formed on the copper foil substrate; and
forming the first patterned structure on top of a first side of the deposited second layer stack,
wherein the stacked graphene structure further comprises the second layer stack, and/or
the method further comprises:
attaching the cover layer in physical contact with the first side of the first patterned structure and the first side of the deposited second layer stack, by gluing the cover layer on top of the first patterned structure and the first side of the deposited second layer stack; and
thereby providing a permanent attachment of the cover layer on the top of the first patterned structure and the first side of the deposited second layer stack.

5. (canceled)

6. The method according to claim 1, wherein the first patterned structure comprises a conductive material including metal or a conductive ink and the first patterned structure is adapted as a conductive electrode.

7. The method according to claim 1, wherein the cover layer comprises an insulating material comprising one selected from the group consisting of a plastic, thermoplastic, glass, and ex sapphire, and wherein the cover layer is arranged to form a base on which the stacked graphene structure will rest, and/or
wherein the cover laver comprises the plastic formed of a dual layer structure, the dual-layer structure comprising a first sub-layer made of ethylene-vinyl acetate, EVA, and a second sub-layer made of polyethylene terephthalate, PET.

8. (canceled)

9. The method according to claim wherein the method further comprises:
separating the stacked graphene structure from the copper foil substrate detaching the stacked graphene structure such that a second side of the graphene layer opposite to the first side of the graphene layer is exposed and/or
the method further comprises:
detaching the stacked graphene structure from the copper foil substrate by one selected from the group consisting of an electrochemical delamination, a mechanical delamination, and an etching process.

10. (canceled)

11. The method according to claim 9, wherein the method further comprises:
forming a third layer stack by depositing the third layer stack on the top of the exposed second side of the graphene layer which is separated from the copper foil substrate; and/or
forming a second patterned structure extending above the second side of the graphene layer.

12. A stacked graphene structure detachably arranged and formed on a copper foil substrate wherein the stacked graphene structure comprises:
a graphene layer formed on the copper foil substrate;
a first patterned structure extending above a first side of the graphene layer formed on the copper foil substrate; and
an attached cover layer over the first patterned structure and the graphene layer.

13. The stacked graphene structure according to claim 12, wherein the stacked graphene structure further comprises:
a second layer stack, made of Parylene N dielectric material, arranged between the graphene layer and the first patterned structure, the second layer stack being deposited on the top of the first side of the graphene layer; wherein the first patterned structure is arranged on the top of a first side of the deposited second layer stack.

14. A graphene-based sensor device or a graphene-field effect transistor device comprising a stacked graphene structure fabricated by the method according to claim 1.

15. A graphene-field effect transistor device comprising the stacked graphene-based structure according to claim 12, the graphene-field effect transistor device comprising:
a graphene layer having a first side and a second side opposite the first side;
a gate dielectric layer stack made of Parylene N arranged at the first side of the graphene layer;
a first patterned gate electrode arranged at a first side of the gate dielectric layer stack;
a cover layer attached over the first patterned gate electrode and the first side of the gate dielectric layer stack, the attached cover layer configured to encompass the first patterned gate electrode and further to support the first patterned gate electrode, the gate dielectric layer stack, and the graphene layer; and
a second pattered electrode structure comprising a first source electrode portion and a second drain electrode portion arranged at opposite ends of the graphene layer,
wherein the second side of the graphene layer is exposed.

16. The graphene-field effect transistor device according to claim 15, wherein the graphene-field effect transistor device further comprises:
a cover dielectric layer arranged at the second side of the graphene layer, and configured to cover the exposed second side of the graphene layer.

17. A method of fabricating a stacked graphene structure, the method comprising:
forming a first patterned structure extending above a first side of a cover layer configured to support the first patterned structure, thereby forming a pre-patterned cover layer, wherein the first patterned structure is made of a conductive material; and
attaching the pre-patterned cover layer over a graphene layer formed on a copper foil substrate, wherein the stacked graphene structure comprises at least the graphene layer and the attached pre-patterned cover layer.

18. The method according to claim 17, wherein the method further comprises:
attaching the pre-patterned cover layer, by gluing the pre-patterned cover layer on the top of a first side of the graphene layer; such that a first side of the first patterned structure, and a first surface of the cover layer are arranged in physical contact with the first side of the graphene layer; and
thereby providing a permanent attachment of the pre-patterned cover layer on the top of the first side of the graphene layer, and/or
the method further comprises:
separating the stacked graphene structure from the copper foil substrate by detaching the stacked graphene structure such that a second side of the graphene layer opposite to the first side of the graphene layer is exposed.

19. (canceled)

20. The method according to claim 18, wherein the method further comprises:
patterning the graphene layer in the detached stacked graphene structure in order to form a patterned graphene layer, wherein the patterned graphene layer is arranged to cover a first side of the first patterned structure and wherein the second side of the patterned graphene layer is exposed.

21. The method according to claim 17, wherein the pre-patterned cover layer comprises an insulating material comprising one selected from the group consisting of a plastic, thermoplastic, glass or sapphire, and wherein the pre-patterned cover layer is arranged to form a base on which the stacked graphene structure will rest.

22. The method according to claim 21, wherein the pre-patterned cover layer comprises the plastic formed of a dual-layer structure, the dual layer structure comprising a first sub-layer made of ethylene-vinyl acetate, EVA, and a second sub-layer made of polyethylene terephthalate, PET.

23. A stacked graphene structure detachably arranged and formed on a copper foil substrate, wherein the stacked graphene structure comprises:
a graphene layer formed on the copper foil substrate; and
a pre-patterned cover layer permanently attached on the top of a first side of the graphene layer, wherein the pre-patterned cover layer comprises a first patterned structure made of a conductive material and extending above a first side of the pre-patterned cover layer configured to support the first patterned structure.

24. The stacked graphene structure according to claim 23, wherein when the stacked graphene structure is separated from the copper foil substrate, the stacked graphene structure comprises:
a patterned graphene layer, wherein the patterned graphene layer is arranged to cover a first side of the first patterned structure and wherein a second side of the patterned graphene layer is exposed.

25. A graphene-based sensor device comprising a stacked graphene structure fabricated by the method according to claim 17.
